(19) United States
(12) Patent Application Publication
(10) Pub. No.: US 2007/0211530 A1
(43) Pub. Date: Sep. 13, 2007

(54) DATA RECORDING METHOD OF SEMICONDUCTOR INTEGRATED CIRCUIT DEVICE

(76) Inventor: Takeshi NAKANO, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/683,604

(22) Filed: Mar. 8, 2007

(30) Foreign Application Priority Data
Mar. 9, 2006 (JP) 2006-064454

(51) Int. Cl. G11C 14/00; G11C 16/04; G11C 11/34

(52) U.S. Cl. 365/185.08; 365/185.11; 365/185.03

(57) ABSTRACT

A data recording system of a semiconductor integrated circuit device having a memory area is disclosed. The semiconductor integrated circuit device is equipped with a memory area that includes a binary area and a multi-level area. The semiconductor integrated circuit device records, in the binary area, data transmitted from a host device as binary data. Further, when no access is provided from the host device, the semiconductor integrated circuit device copies, to the multi-level area, the data recorded in the binary area as multi-level data.

### CROSS-REFERENCE TO RELATED APPLICATIONS

This application is based upon and claims the benefit of priority from prior Japanese Patent Application No. 2006-064454, filed Mar. 9, 2006, the entire contents of which are incorporated herein by reference.

### BACKGROUND OF THE INVENTION

1. Field of the Invention

The present invention relates to a data recording system of a semiconductor integrated circuit device, and particularly to a data recording system of a semiconductor integrated circuit device that comprises a data rewritable nonvolatile semiconductor memory.

2. Description of the Related Art

A data rewritable nonvolatile semiconductor memory is known as one of storage means for recording media such as memory cards, and demands for such semiconductor memory are expanding. Recording media require large-scale recording capacities. Thus, in the nonvolatile semiconductor memory, increasing the memory capacity is underway. In addition to the achievement of high integration, a multi-level technique is also under development. Further, recording media require fast data writing and reading in addition to their large-scale recording capacities. However, although a memory employing a multi-level technique, a so-called multi-level memory is superior to a binary memory in memory capacity, it is inferior in write speed and read speed.

A semiconductor memory device that operates in both of a multi-level mode and a binary mode is described in Jpn. Pat. Appln. KOKAI Publication Nos. 2001-6374 and 2005-115982, for example.

### BRIEF SUMMARY OF THE INVENTION

According to one aspect of the present invention, there is provided a data recording method of a semiconductor integrated circuit device which has a memory area including a binary area and a multi-level area, and exchanges data between the memory area and a host device, the method comprises, recording data transmitted by the host device as binary data in the binary area, and copying the data recorded in the binary area as multi-level data to the multi-level area when no access is provided from the host device.

### BRIEF DESCRIPTION OF THE SEVERAL VIEWS OF THE DRAWING

FIG. 1 is a view showing an example of a memory card;

FIG. 2 is a view showing an example of signal assignment with respect to signal pins;

FIG. 3 is a block diagram depicting an example of a hardware configuration of the memory card;

FIG. 4 is a plan view showing an example of a NAND-type flash memory;

FIG. 5 is a view showing a data recording system according to a first embodiment of the present invention;

FIG. 6 is a view showing flows of control and data in a system;

FIG. 7 is a view showing an example of a memory area;

FIG. 8 is a view showing a data recording system according to a second embodiment of the present invention;

FIG. 9 is a view showing a data recording system according to a third embodiment of the present invention;

FIG. 10 is a flowchart showing an example of a flow of updating a multi-level area in the data recording system according to the third embodiment of the present invention;

FIG. 11 is a view showing a data recording system according to a fourth embodiment of the present invention;

FIG. 12 is a block diagram depicting a first example of cache arrangement in the data recording system according to the fourth embodiment of the present invention;

FIG. 13 is a block diagram depicting a second example of cache arrangement in the data recording system according to the fourth embodiment of the present invention;

FIG. 14 is a block diagram depicting a third example of cache arrangement in the data recording system according to the fourth embodiment of the present invention;

FIG. 15 is a block diagram depicting a fourth example of cache arrangement in the data recording system according to the fourth embodiment of the present invention;

FIGS. 16A to 16E are views each showing an example of a data recording system according to a modified example of the fourth embodiment of the present invention;

FIG. 17 is a block diagram depicting an example of a data recording system according to another modified example of the fourth embodiment of the present invention; and

FIG. 18 is a view showing a relationship between a used capacity and an operating speed.

### DETAILED DESCRIPTION OF THE INVENTION

Now, some embodiments of the present invention will be described with reference to the accompanying drawings. In the figures, like constituent elements are designated by like reference numerals. In the present embodiments, a nonvolatile semiconductor memory utilized in a recording medium such as a memory card is illustrated as an example of a semiconductor integrated circuit device. An example of the nonvolatile semiconductor memory is a flash memory. An example of the flash memory is a NAND-type flash memory.

### First Embodiment

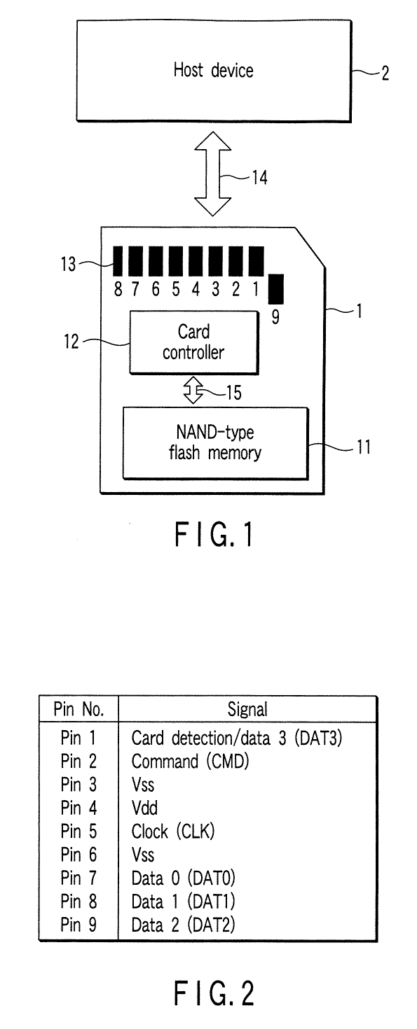

FIG. 1 is a view showing an example of a memory card.

As shown in FIG. 1, a memory card 1 transmits data to and receives data from a host device 2 via a bus interface 14. The memory card 1 is formed to be removable from a slot provided in the host device 2.

The memory card 1 comprises a NAND-type flash memory 11; a card controller 12 that controls this flash memory 11; and a plurality of signal pins (first to ninth pins) 13.

The signal pin 13 serves as a pin electrically connected to the card controller 12, and functions as an external pin of the memory card 1. FIG. 2 shows an example of assignment of signals with respect to the first to ninth pins in the signal pin 13.

As shown in FIG. 2, data 0 to data 3 are assigned to a seventh pin, an eighth pin, a ninth pin, and a first pin, respectively. The first pin is assigned to a card detection signal as well as data 3. Further, the second pin is assigned to a command; the third pin and the sixth pin each are assigned to a ground electrical potential Vss; the fourth pin is assigned to a power supply electrical potential Vdd; and the fifth pin is assigned to a clock signal.

The signal pin 13 and the bus interface 14 are used for communication between a host device controller (not shown) in the host device 2 and the memory card 1. For example, the host device controller communicates a variety of signals and data with the card controller 12 in the memory card 1 via the first to ninth pins. For example, when data is written in the memory card 1, the host device controller transmits a write command to the card controller 12 via the second pin. At this time, the card controller 12 captures a write command assigned to the second pin in response to a clock signal supplied to the fifth pin. The second pin assigned to command entry is arranged between the first pin for data 3 and the third pin for the ground electrical potential Vss.

In contrast, communication between the flash memory 11 and the card controller 12 is made via an interface for a NAND-type flash memory, for example, an 8-bit IO line (data line) 15.

When the card controller 12 writes data into the flash memory 11, the card controller 12 sequentially inputs via the IO line 15 a data input command 80h, a column address, a page address, data, and a program command 10h to the flash memory 11. The lowercase letter “h” in the command 80h used here denotes a hexadecimal number, and in practice, an 8-bit signal “10000000” is assigned to the 8-bit IO line 15 in parallel. Namely, a command of a plurality of bits is assigned in parallel in the interface for the NAND-type flash memory. In addition, in the interface for the NAND-type flash memory, commands for the flash memory 11 and data are communicated while the IO line 15 is used in common.

Therefore, an interface for communication between the host device controller and the card controller 12 is different from that for communication between the flash memory 11 and the card controller 12.

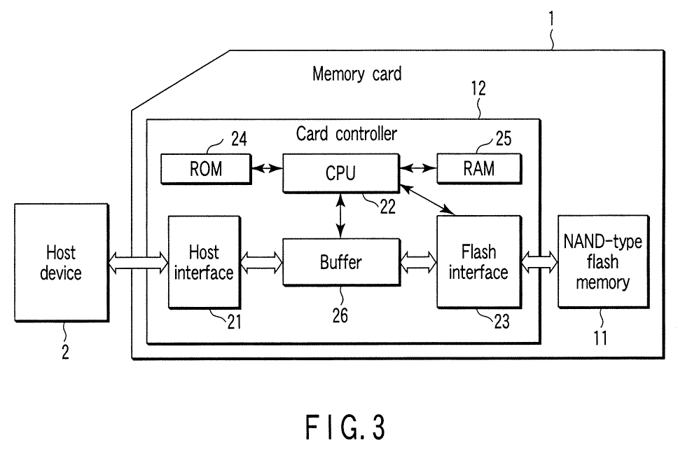

FIG. 3 is a block diagram depicting an example of a hardware configuration of a memory card.

The host device 2 comprises hardware and software for providing an access to the memory card 1. The memory card 1 operates upon receiving power supply when the card is connected to the host device 2, and then, carries out a processing operation responsive to an access from the host device 2.

In the flash memory 11, an erasing block size at the time of erasing (block size in units of erasing) is defined as a predetermined size (256 KB, for example). In addition, data is written to and read from this flash memory 11 in units called pages (for example, 2 KB).

The card controller 12 manages a physical state in the flash memory 11 (for example, which number of logical sector address data is contained in which physical block address or which block is in an erasing state). The card controller 12 has: a host device interface 21; a central processing unit (CPU) 22; a flash interface 23; a read-only memory (ROM) 24; a random access memory (RAM) 25; and a buffer 26.

The host device interface 21 carries out interface processing between the card controller 12 and the host device 2.

The CPU 22 controls an operation of the whole memory card 1. The CPU 22 creates a variety of tables in the RAM 25 by reading into the RAM 25 the firmware (control program) stored in the ROM 24, and then, executing a predetermined processing operation when the memory card 1 has been powered.

In addition, the CPU 22 receives a write command, a read command, an erase command from the host device 2, and then, executes a predetermined processing operation for the flash memory 11 or controls a data transfer processing operation through the buffer 26.

The ROM 24 stores a control program, for example, controlled by means of the CPU 22. The RAM 25 is used as a work area of the CPU 22, and stores the control program and/or a variety of tables. The flash interface 23 carries out interface processing between the card controller 12 and the flash memory 11.

The buffer 26 temporarily stores a predetermined amount of data (data for one page, for example) when the data sent from the host device 2 is written to the flash memory 11 or temporarily stores a predetermined amount of data when the data read from the flash memory 11 is sent to the host device 2.

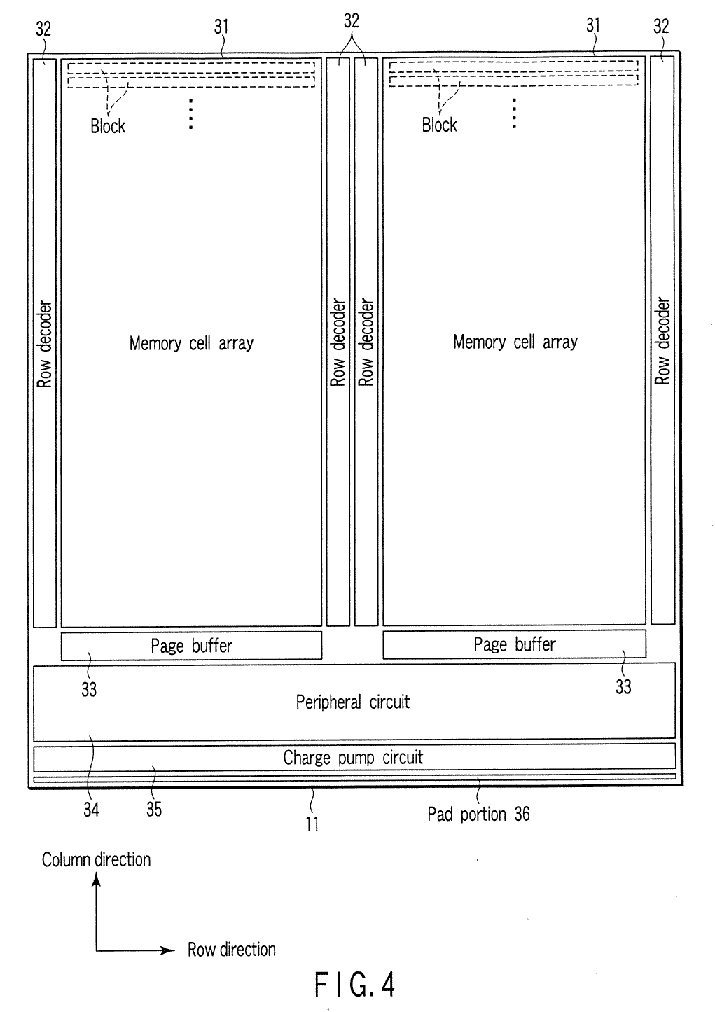

FIG. 4 is a plan view showing an example of a NAND-type flash memory.

As shown in FIG. 4, the NAND-type flash memory 11 includes a memory cell array 21, a row decoder 32, a page buffer 33, a peripheral circuit 34, a charge pump circuit 35, and pad portion 36.

In the memory cell array 31, nonvolatile semiconductor memory cells (not shown) are arranged in a matrix manner. In the present example, there are two memory cell arrays 31 in a NAND-type flash memory chip.

The row decoder 32 selects a row of the memory cell array 31. In the NAND-type flash memory 11, the row decoder 32 includes a decoder that selects a block in the memory cell array 31 and a decoder that selects a word line in the block. In the present example, the row decoder 32 is arranged adjacent to both of ends along a column direction of the memory cell array 31.

The page buffer 33, the peripheral circuit 34, the charge pump circuit 35, and the pad portion 36 are sequentially arranged adjacent to one of the ends in a row direction of the memory cell array 31.

The page buffer 33 is one element in the data circuit. The page buffer 33 temporarily stores write data written to the memory cell array 31, for example, write data for one page, or temporarily stores read data read from the memory cell array 31, for example, read data for one page.

The peripheral circuit 34 includes a memory periphery circuit, for example, a data input/output buffer, a command interface, a state machine and the like.

The charge pump circuit 35 is one of step-up circuits. The charge pump circuit generates an electrical potential required for data erasing and data writing, for example, an electrical potential that is higher than an external power supply electrical potential or a chip internal power supply electrical potential used in a chip.

A pad is arranged at the pad portion 36. Pads are electrically connected to a data input/output buffer in the peripheral circuit 34 and a command interface. Each pad serves as external electrical contact point of the NAND-type flash memory 11, and is electrically connected to the flash interface 23 mentioned previously. The data output from the flash interface 23 and a control signal is input to the data input/output buffer and the command interface via the pads. In addition, the data output from the data input/output buffer is input to the flash interface 23 via the pad. In the present example, the pad portion 36 is arranged adjacent to one of the ends along a row direction of a chip. For example, this pad portion is arranged along the charge pump circuit 35.

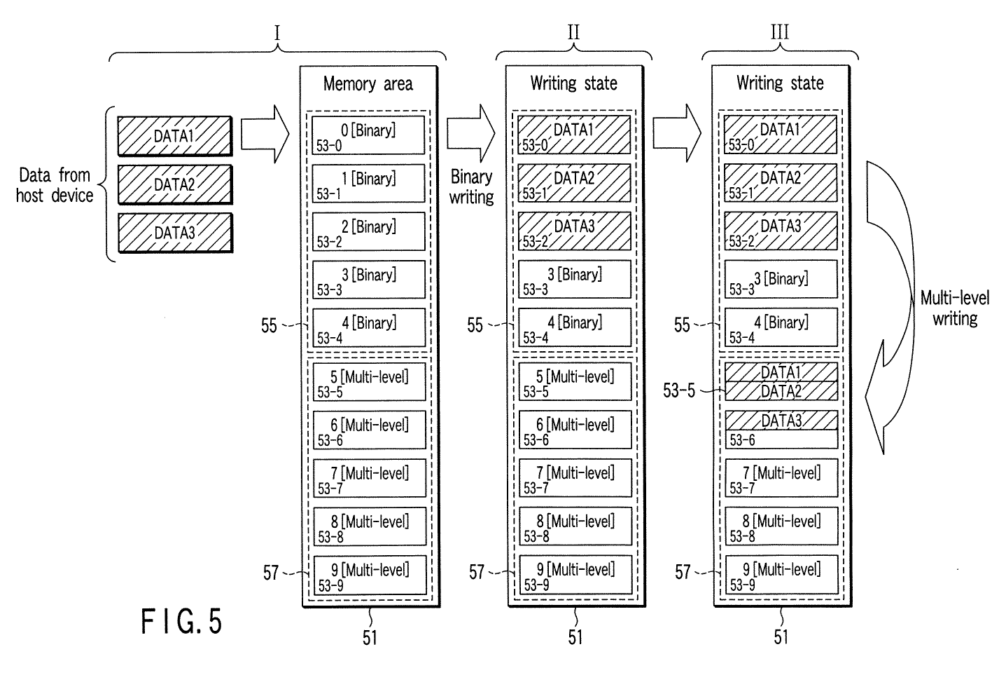

FIG. 5 is a view showing a data recording system of the NAND-type flash memory according to the first embodiment.

FIG. 5 shows a case in which data sent from a host device is recorded in a memory area 51. A specific example of the memory area 51 described in the present example is the memory cell array 31 shown in FIG. 4, for example, without being limited thereto.

First, as shown in state I of FIG. 5, data (DATA 1 to DATA 3) transmitted from the host device 2 is input to the memory area 51 of the NAND-type flash memory 11. The data (DATA 1 to DATA 3) is recorded in the memory area 51. The memory area 51 of the present example includes a plurality of unit areas, for example, 10 unit areas 53-0 to 53-9 in FIG. 5. Examples of the unit area 53 are sectors, blocks, pages and the like. The memory area 51 of the present example includes a binary area 55 and a multi-level area 57. In FIG. 1, five unit areas 53-0 to 53-4 are included in the binary area 55 and the remaining five unit areas 53-5 to 53-9 are included in the multi-level area 57. The binary area 55 records data in a binary manner. The multi-level area 57 records data in a multi-level manner.

The data (DATA 1 to DATA 3) is recorded in the binary area 55, as shown in state II of FIG. 5. In the present example, the data is recorded in the unit area 53-0 to 53-2.

Then, the card controller 12 or the NAND-type flash memory 11 copies the data recorded in the binary area 55 to the multi-level area 57, as shown in state III of FIG. 5, when it is judged that no access is provided from the host device 2, for example. In the present example, the data (DATA 1 to DATA 3) recorded in the unit areas 53-0, 53-1, and 53-2 are copied to the unit areas 53-5 and 53-6.

In the present example, the data (DATA 1 to DATA 3) recorded in the binary area 55 is copied to the multi-level area 57, and then, the data (DATA 1 to DATA 3) recorded in the binary area 55 is left in the binary area 55 without being erased therefrom. In the case where the host device 2 has made a request for reading the data (DATA 1 to DATA 3), the data (DATA 1 to DATA 3) is read from the binary area 55. This is advantageous in that a read speed is not lowered.

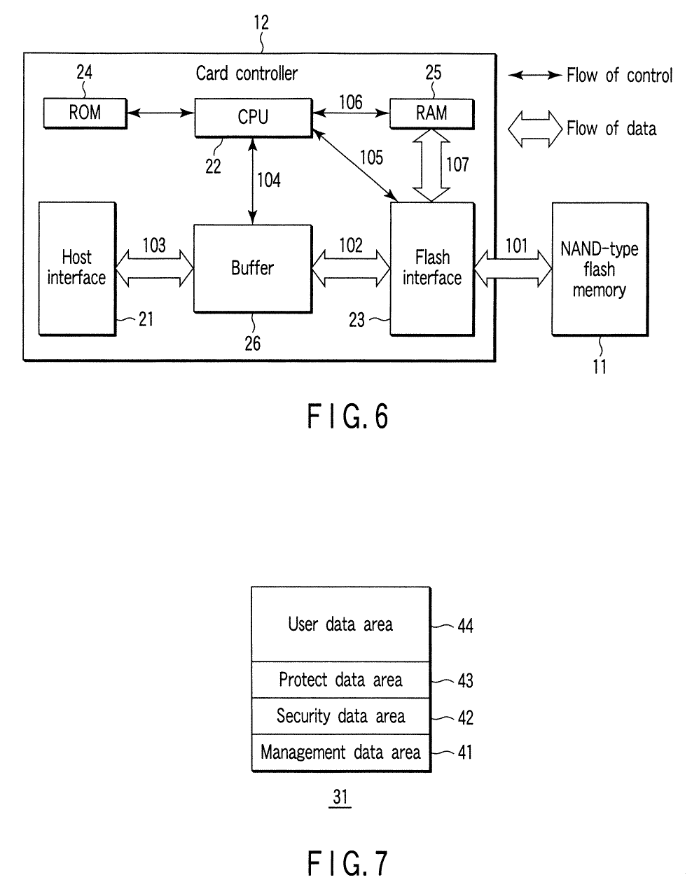

FIG. 6 is a view showing flows of control and data in a system.

At the time of implementing the present example, the card controller 12 should know which address of the NAND-type flash memory 11 is in the binary area 55 and which address is in the multi-level area 57, for example. That is, binary/multi-level area management is acceptable. In the area management, for example, it is acceptable to create a binary/multi-level area management table indicating which address of the NAND-type flash memory 11 is in the binary area 55 and which address is in the multi-level area 57. The above areas should be managed in accordance with this binary/multi-level area management table. Here, an example of this management is shown below.

An example of the management is an example of recording the binary/multi-level area management table in the NAND-type flash memory 11.

First, the binary/multi-level area management table records data in the memory area 51 of the flash memory 11, for example, at the time of shipment. Namely, the flash memory 11 incorporated in the memory card 1 has recorded therein the binary/multi-level area management table.

In order to read the binary/multi-level area management table from the flash memory 11, the CPU 22 issues an instruction for reading the management table to the flash interface 23 (see reference numeral 105). The flash interface 23 transmits the received instruction to the flash memory 11. The flash memory 11 reads the binary/multi-level area management table from the memory area 51 in accordance with the received instruction, and then, the read binary/multi-level area management table is loaded into the RAM 25 via the flash interface 23. The CPU 22 refers to the binary/multi-level area management table loaded into the RAM 25 at the time of data writing control, for example. In this manner, the CPU 22 can provide an access to the binary area 55 of the flash memory 11 at the time of data writing.

The memory area 51 corresponds to the memory cell array 31 in the present example. FIG. 7 shows an example thereof.

As shown in FIG. 7, the memory area 51 is divided into a plurality of areas according to data to be stored. The memory area 51 comprises a management data area 41, a security data area 42, a protect data area 43, and a user data area 44, for example, as data storage areas.

The management data area 41 mainly stores management information relating to a memory card. For example, security information contained in the memory card 1 or card information such as media ID is stored in the management data area 41.

The security data area 42 stores key information used for encoding or security data used at the time of authentication. The security data area 42 is an area inaccessible from the host device 2, for example.

The protect data area 43 stores important data. The protect data area 43 is an area accessible only in the case where validity of the host device 2 is proved by mutual authentication with the host device 2 connected to the memory card 1, for example.

The user data area 44 stores user data. The user data area 44 is an area freely accessible from, and freely usable by, a user who uses the memory card 1.

The above binary/multi-level area management table contains information that must not be erased carelessly. Therefore, this information should be stored in an area inaccessible from the host device 2 or accessible only when a predetermined condition is met. Therefore, the binary/multi-level area management table may be stored in each of the security data area 42 and the protect data area 43, for example.

In the present example, the binary/multi-level area management table read from the flash memory 11 is loaded into the RAM 25 of the card controller 12. The RAM 25 is a volatile semiconductor memory. If the power is turned off, the binary/multi-level area management table data loaded into the RAM 25 is lost. In order to recover the lost data, in the present example, the binary/multi-level area management table is read and loaded into the RAM 25 every time power is supplied.

The RAM 25 may be a nonvolatile semiconductor memory without being limited to a volatile semiconductor memory. For example, a ferroelectric semiconductor memory (FeRAM) may be utilized for the RAM 25. In the case where a nonvolatile semiconductor memory is utilized for the RAM 25, the binary/multi-level area management table may be recorded in this RAM 25 after reading the table before shipment in a manufacturing factory of the memory card 1, and then, loading it into the RAM 25. Alternatively, at the time of starting use in market, for example, this table may be recorded in this RAM 25 after reading the table at the initialization of the memory card 1 and loading it into the nonvolatile RAM 25.

In the first embodiment, data (DATA 1 to DATA 3) transmitted from the host device 2 is recorded in the binary area 55 among the memory area 51 including the binary area 55 and the multi-level area 57. The data (DATA 1 to DATA 3) is written to the memory area 51 in accordance with writing of multi-level data. The writing of the binary data is high in write speed in comparison with that of the multi-level data. For example, when multi-level data is written to memory cells, a plurality of writing threshold-value levels of memory cells must be set between an erasing level and an intermediate voltage Vpass. For example, in the case of four-level data, three writing threshold value levels are set in addition to an erasing level. On the other hand, in the case of binary data, only one writing threshold value level may be set in addition to an erasing level.

As described above, according to the first embodiment, data (DATA 1 to DATA 3) is recorded as binary data in the binary area 55, so that the lowering of the write speed of the NAND-type flash memory 11 can be restrained. The first embodiment is directed to the memory card 1. If the lowering of the write speed of the NAND-type flash memory 11 is restrained, the memory card 1 having a high data write speed can be obtained.

If the data (DATA 1 to DATA 3) transmitted from the host device is recorded as only binary data, the remaining recording space of the memory area 51 decreases rapidly. Therefore, in the first embodiment, the data (DATA 1 to DATA 3) recorded in the binary area 55 is copied as multi-level data to the multi-level area 57. As a copying time interval, there is utilized a time interval at which an access such as data writing, data read, or state request is not provided to the NAND-type flash memory 11. As an example of determining this time interval, it is sufficient if an elapse of a predetermined time is detected after input of a control signal to the NAND-type flash memory 11 or after data input or output. While a circuit for detecting the elapse of the predetermined time can be provided in the NAND-type flash memory 11, the circuit can also be provided in the card controller 12. The circuit may be provided in either of them. After the predetermined time has elapsed, the NAND-type flash memory 11, as its internal operation, starts a data copy operation based on its own judgment or in accordance with an instruction from the card controller 12. The predetermined time may be properly set in consideration of an access frequency from the host device 2, an access frequency from the card controller 12 and the like.

The data (DATA 1 to DATA 3) recorded in the binary area 55 can be erased because the data is copied to the multi-level area 57. Erasing the data (DATA 1 to DATA 3) recovers the remaining recording space of the memory area 51. However, in the first embodiment, the data (DATA 1 to DATA 3) is left in the binary area 55 without erasing it, for example, until no available space is left in the binary area 55. In the case where the host device 2 makes a request for reading the data (DATA 1 to DATA 3), the data (DATA 1 to DATA 3) in a copy source left in the binary area 55 is read instead of reading the data (DATA 1 to DATA 3) copied to the multi-level area 57. In comparison with reading the binary data, it takes long to read the multi-level data. For example, in reading the multi-level data, data read from memory cells is repeated while a read voltage applied to a word line is varied, or discrimination of the read data is repeated while a reference electrical potential of a sense amplifier is varied. Therefore, in the present example, the data (DATA 1 to DATA 3) recorded in the binary area 55 is left in the binary area 55, for example, until no available space is left in the binary area 55. In the case where the host device 2 makes a request for reading the data (DATA 1 to DATA 3) left in the binary area 55, the data (DATA 1 to DATA 3) in a copy source left in the binary area 55 is read instead of reading the data (DATA 1 to DATA 3) copied to the multi-level area 57.

As described above, according to the first embodiment, if the data (DATA 1 to DATA 3) in a copy source is left in the binary area 55, the data (DATA 1 to DATA 3) in the copy source is read in accordance with binary read, thus making it possible to restrain the lowering of the read speed as well as the write speed of the NAND-type flash memory 11. Of course, if the lowering of the read speed of the NAND-type flash memory 11 is restrained, the memory card 1 using the memory can restrain the lowering of the data read time as well.

### Second Embodiment

A second embodiment is an example relating to an operating state in the case where the available space of a binary area 55 is reduced.

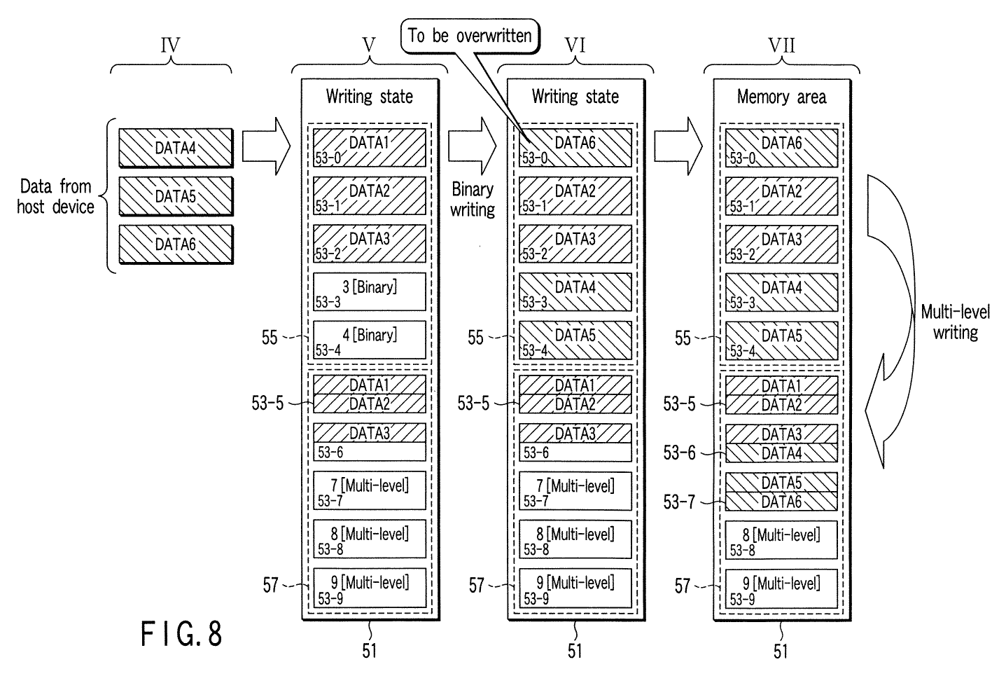

FIG. 8 is a view showing a data recording system of a NAND-type flash memory according to the second embodiment of the present invention.

As shown in state IV of FIG. 8, assume that data (DATA 4 to DATA 6) for three unit areas has been sent from a host device 2. At this time, as shown in state V, assume that only two unit areas 53-3 and 53-4 are provided as available spaces of the binary area 55. In this case, there occurs shortage of one unit area.

When available space is eliminated from the binary area 55, in the second embodiment, the data transmitted from the host device 2 is recorded in an overwritten manner in a portion at which the data copied to a multi-level area 57 exists among the data recorded in the binary area 55.

The available spaces of the binary area 55 of the present example are two unit areas, the unit areas 53-3 and 53-4, as shown in state V. Of the data (DATA 4 to DATA 6) transmitted from the host device 2, the data (DATA 4, DATA 5) for the first two unit areas is recorded as it is in the unit areas 53-3 and 53-4 serving as available spaces. Data that cannot be recorded, the data (DATA 6) in the present example, is recorded in an overwritten manner in a portion at which the data copied to a unit area of the multi-level area 57 exists among the data recorded in a unit area of the binary area 55. In the present example, as shown in state VI, the data is recorded in an overwritten manner in a unit area 53-0 in which data has been first recorded.

In the present example, as in the first embodiment, data is sequentially recorded in the binary area 55, for example, in order of unit areas 53-0, 53-1, . . . , 53-4. In this duration, the recorded data is copied from the binary area 55 to the multi-level area 57 utilizing a time interval at which no access is provided to the flash memory 11, as explained in the first embodiment. When no available space is left in the binary area 55 and the copied data exists in the multi-level area 57, the data is overwritten. For example, the data is recorded again from the start in order of the units areas 53-0, 53-1, . . . , 53-4. Namely, if the data copied to the multi-level area 57 exists, data can be overwritten in a unit area of the binary area 55. Therefore, in the present example, if the unit area is established in an overwrite-enable state, overwriting is carried out while the unit areas of recording data are circulated in the binary area 55 like “53-0→53-1→ . . . →53-4→53-0→53-1→ . . . →53-4→53-0→ . . . ” immediately after available space is eliminated from the binary area 55. The overwritten data, i.e., the data (DATA 6) in the present example, is copied from the binary area 55 to the multi-level area 57, utilizing a time interval at which no access is provided to the flash memory 11, as in the first embodiment (see state VII).

As described above, according to the second embodiment, when no available space is left in the binary area 55, the data transmitted from the host device 2 is recorded in an overwritten manner in a portion at which the data copied to the multi-level area 57 exists among the data recorded in the binary area 55. In this manner, even if no available space is left in the binary area 55, the data transmitted from the host device 2 can be recorded in the binary area 55 without being recorded in the multi-level area 57. Therefore, even if no available space is left in the binary area 55, it is possible to restrain the lowering of the write speed of the NAND-type flash memory 11.

### Third Embodiment

A third embodiment presents an example relating to an operating state in the case where the available space of a multi-level area 57 is reduced.

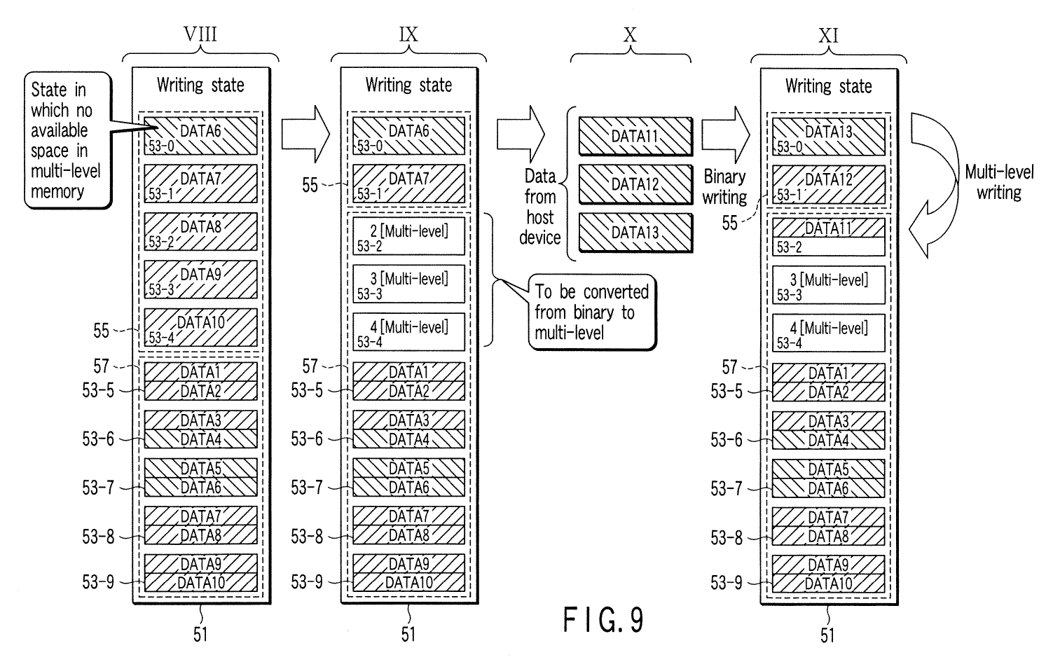

FIG. 9 is a view showing a data recording system of a NAND-type flash memory according to the third embodiment of the present invention.

As shown in state VIII of FIG. 9, assume that available space does not exist in the multi-level area 57. When no available space is left in the multi-level area 57, a binary area 55 is partially changed to the multi-level area 57, as shown in state IX, in the third embodiment.

In unit areas 53-5 to 53-9 of the multi-level area 57, data (DATA 1 to DATA 10) is recorded as shown in states VIII and IX, and no available space exists. Therefore, in the present example, among unit areas 53-0 to 53-4 of the binary area 55, the three unit areas 53-2 to 53-4 are changed from the binary area 55 to the multi-level area 57. Data (DATA 8 to DATA 10) is recorded in these three unit areas 53-2 to 53-4, whereas this data is copied to unit areas 53-8 and 53-9 of the multi-level area 57. Namely, this data is erasable. As described above, in the present example, among the binary area 55, a portion at which the data copied to the multi-level area 57 exists is partially is changed to the multi-level area 57. In the present specification, a change from a binary area to a multi-level area is referred to as “multi-level area update”.

Further, as shown in state X, assume that data (DATA 11 to DATA 13) has been transmitted from a host device 2. This data (DATA 11 to DATA 13) is recorded as binary data in the binary area 55 of a memory area 51.

In the present example, data (DATA 11) is recorded in a unit area 53-0 (by overwriting it in DATA 6). Then, data (DATA 12) is recorded in a unit area 53-1 (by overwriting it in DATA 7). The binary area 55 has two unit areas 53-0 and 53-1.

However, in the present example, data (DATA 13) is further left in a buffer 26, for example, of a card controller 12. In this situation, the binary area 55 becomes short, and the data (DATA 13) cannot be recorded in a flash memory 11. Therefore, as shown in state XI, among the currently transmitted data, recorded data is copied to the multi-level area 57. In the present example, data (DATA 11) is copied from the unit area 53-0 to the unit area 53-2 of the multi-level area 57. The data (DATA 11) recorded in the unit area 53-0 has been copied to the multi-level area 57, thus making it possible to overwrite the unit area 53-0. The data (DATA 13) is recorded as binary data in the unit area 53-0 that can be overwritten.

While the present example has shown an example of copying only the data (DATA 11) from the unit area 53-0 to the unit area 53-2, the unit area 53-2 is included in a multi-level area. Therefore, for example, in the case of a four-value area, data, an amount of which is twice of the unit area 53-0, can be recorded. Therefore, at the time of copying the data (DATA 11), the data (DATA 12) may also be recorded in the unit area 53-2.

Now, an example of a flow of updating a multi-level area will be described below.

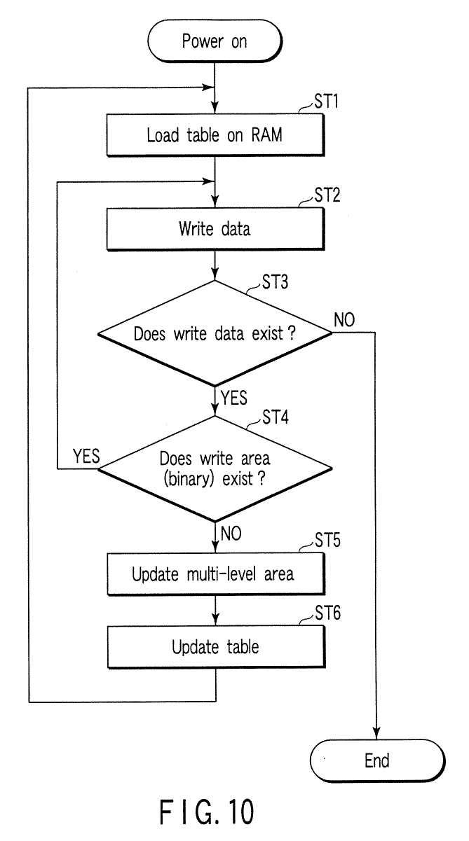

FIG. 10 is a flowchart showing an example of a flow of updating a multi-level area in a data recording system of a NAND-type flash memory according to the third embodiment of the present invention.

First, after power is supplied, a binary/multi-level area management table is loaded into a RAM 25 (STEP 1).

This loading is equivalent to loading of the binary/multi-level area management table as described in the first embodiment.

Default values of the binary/multi-level area management table are maintained in a card controller 12.

Next, data transmitted from the host device 2 is recorded in the flash memory 11 via the card controller 12. The card controller 12 temporarily accumulates in a buffer 26 the data transmitted from the host device 2, delimits the data by unit area 53, for example, and then, transmits the delimited data to the flash memory 11. The transmitted data is recorded in the flash memory 11 (data write: STEP 2).

Next, it is judged whether or not data to be recorded in the flash memory 11 is left in the buffer 26 (whether or not write data exists: STEP 3). If the data to be recorded is not left in the buffer 26 (NO), data recording is terminated. On the other hand, if the data to be recorded is left (YES), the routine proceeds to STEP 4.

In STEP 4, it is judged whether or not available space exists in the binary area 55 (whether or not a write area (binary) exists). If available space exists (YES), the routine reverts to STEP 2 described above and the procedures from data writing are repeated. On the other hand, if available space does not exist (NO), the routine proceeds to STEP 5.

In STEP 5, a multi-level area is updated. The multi-level area is updated as described above. For example, among the binary area 55, a portion at which the data copied to the multi-level area 57 exists is partially changed to a multi-level area.

Next, the binary/multi-level area management table is updated (STEP 6). Next, the routine reverts to STEP 1 in which the updated binary/multi-level area management table is loaded into the RAM 25. In this manner, the default values of the binary/multi-level area management table are updated to an update value, and the update value is maintained in the card controller 12. Then, the routine proceeds to STEP 2 in which the procedures after STEP 2, STEP 3 to STEP 6 in the present example, are repeated.

As described above, according to the third embodiment, when available space is eliminated from the multi-level area 57, the binary area 55 is partially changed to the multi-level area 57. For example, among the binary area 55, a portion at which the data copied to the multi-level area 57 exists is changed to the multi-level area 57. In this manner, even if available space is eliminated from the multi-level area 57, the recording capacity of the flash memory 11 increases so that a large-scale recording capacity can be maintained.

Further, according to the third embodiment, when the binary area 55 is changed to the multi-level area 57, the area is partially changed without being wholly changed at one time. In other words, the binary area 55 is changed to the multi-level area 57 in a stepwise manner. By changing the area in the stepwise manner, there can be attained an advantage that the binary area 55 can be left in the memory area 51. The data transmitted from the host device 2 is recorded in the left binary area 55. In this manner, there can be attained an advantage that the lowering of a write speed of the NAND-type flash memory 11 can be restrained in comparison with a case of wholly changing the binary area 55 to the multi-level area 57 at one time.

### Fourth Embodiment

A fourth embodiment presents an example relating to a data recording system capable of restraining the lowering of a data write speed.

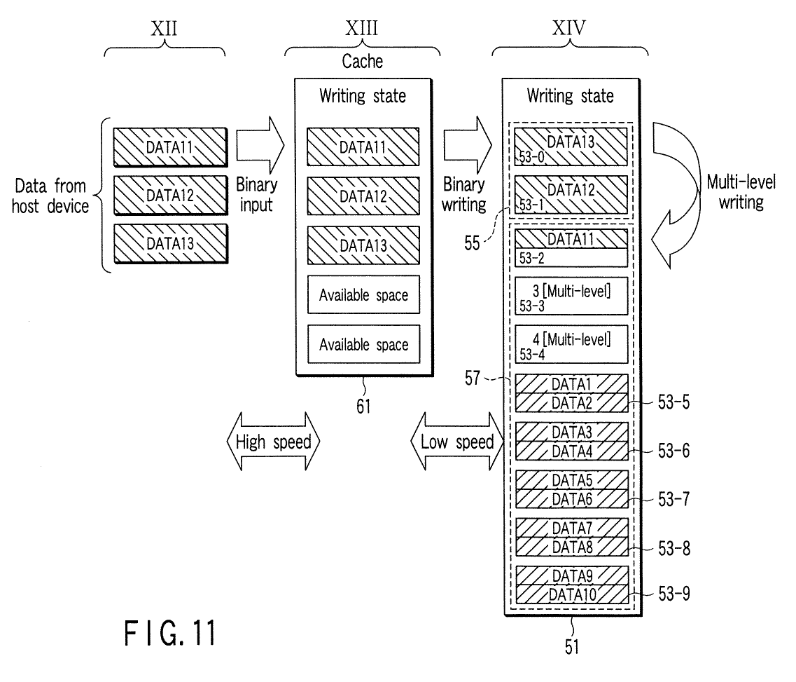

FIG. 11 is a view showing a data recording system of a NAND-type flash memory according to the fourth embodiment of the present invention.

As recording continues in a NAND-type flash memory 11, the available space of a memory area 51 is reduced. As the available space of the memory area is reduced, reading/writing by a multi-level is prone to occur. In order to restrain the lowering of an operating speed caused by such reading/writing, the data transmitted from a host device may be temporarily stored in a cache.

In the present embodiment, as shown in state XII of FIG. 11, data (DATA 11 to DATA 13) transmitted from a host device 2 is temporarily recorded as binary data in a cache 61, as shown in state XIII. Then, as shown in state XIV, the data (DATA 1 to DATA 13) stored in the cache 61 is recorded in a binary area 55 of the memory area 51.

As described above, according to the fourth embodiment, the cache 61 is further provided; the data transmitted from the host device 2 is stored in the cache 61; and then, the data stored in the cache 61 is recorded in the binary area 55 of the memory area 51. In this manner, it becomes possible to restrain the lowering of a data write speed.

In addition, as shown in state XIV of FIG. 11, in the case where the capacity of the binary area 55 described in the third embodiment becomes short, an operation of transferring the data recorded in the binary area 55, and then, creating available space in the binary area 55 to the multi-level area 57, is made. A multi-level writing operation is made when transferring the data to the multi-level area 57. It takes long to make the multi-level writing operation in comparison with a binary writing operation. An adequate time is required to complete a recording operation as shown in state XVI.

The host device 2 often disables another operation while data is recorded in a memory card 1, for example. For example, photographing by a user is disabled if a digital still camera is taken as an example. Photographing is disabled while data is recorded in the memory card 1. It is inconvenient to the user that the operation of recording data in the memory card 1 is slow. This also applies to a camera-equipped cellular phone.

In this regard, in the fourth embodiment, the data transmitted from the host device 2 is stored in the cache 61 at high speed. At a time point when this storage has been completed, for example, data transmission/receiving between the memory card 1 and the host device 2 is temporarily stopped. During this temporary stoppage, for example, in the host device 2, the user does not need to wait for a long time to record data as long as an enable state of another operation is established.

After data is stored in the cache 61, the cache 61 records the stored data in the memory area 51 of the flash memory 11. A speed of writing data into the memory area 51 is low in comparison with a speed of storing data in the cache 61, and is time-consuming. However, according to the fourth embodiment, it is possible to terminate a recording operation at a time point when the data from the host device 2 has been temporarily stored in the cache 61. Therefore, a data recording time to be received by the host device 2 or to be felt by the user can be reduced in comparison with a case of data recording without interposing the cache 61. This is equivalent to the fact that the lowering of the speed of writing data into the memory card 1 has been restrained.

(Example of Cache Arrangement)

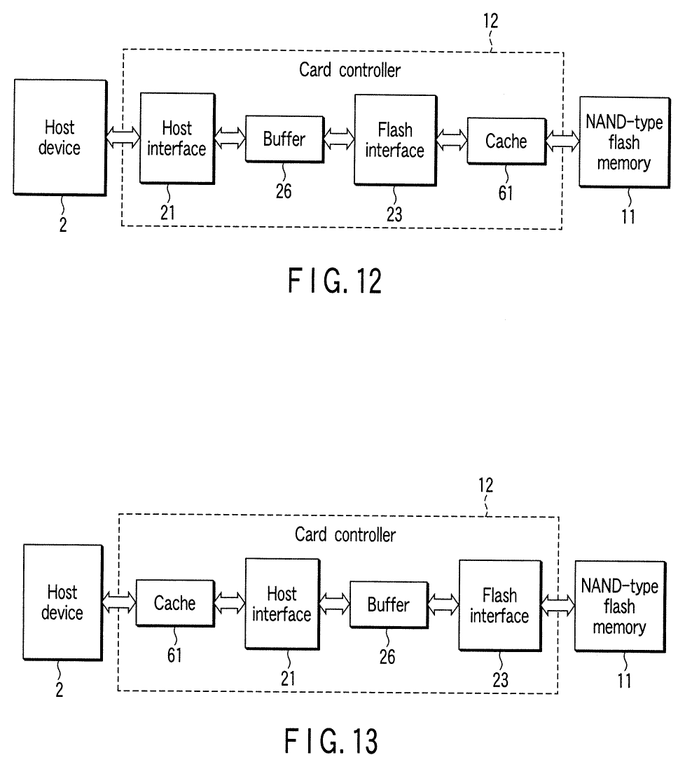

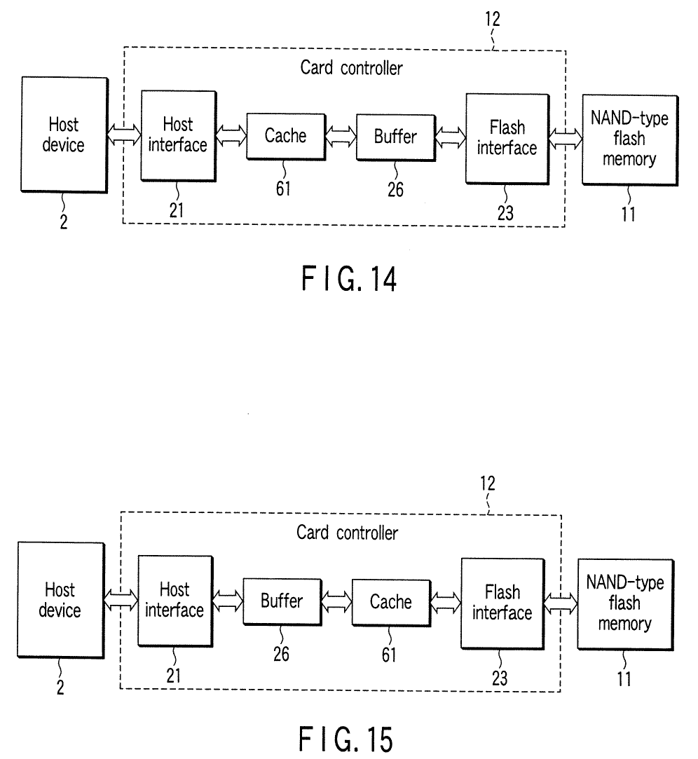

As described above, from the viewpoint of speeding up transmission/receiving of data between the host device 2 and the memory card 1, the cache 61 may be arranged between the card controller 12 and the NAND-type flash memory 11. The cache 61 may be arranged between a flash interface 23 and the NAND-type flash memory 11, as shown in FIG. 12; between the host device 2 and a host interface 21, as shown in FIG. 13; between the host interface 21 and a buffer 26, as shown in FIG. 14; or between the buffer 26 and the flash interface 23, as shown in FIG. 15.

(Modified Example of Fourth Embodiment)

By utilizing a cache 61, data management can be carried out as described below or a data transfer system can be employed.

In the case where a nonvolatile semiconductor memory is used for the cache 61 and data is stored in this nonvolatile semiconductor memory cache 61, when a card is inserted next, the data stored in the nonvolatile semiconductor memory cache 61 can be recorded as long as the data is unrecorded in a memory area 51.

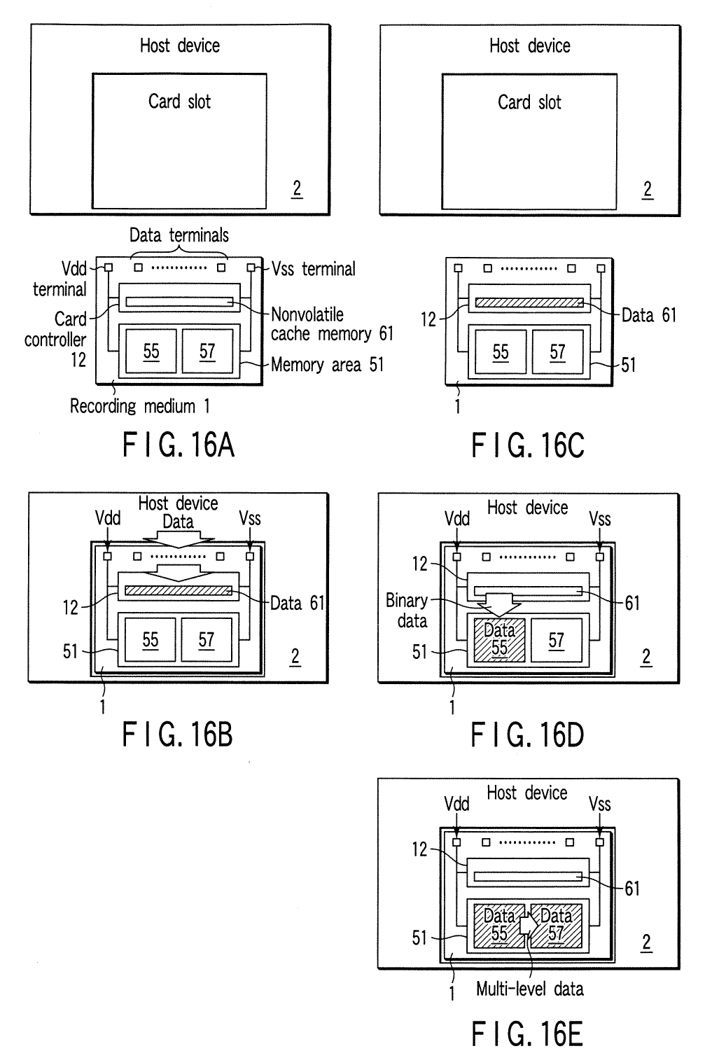

This recording is shown in FIGS. 16A to 16E.

FIG. 16A shows a state in which a recording medium 1 (for example, memory card) is not inserted in a card slot of a host device 2.

When the recording medium 1 shown in FIG. 16A is inserted into the card slot of the host device 2 as shown in FIG. 16B, power Vdd, Vss is supplied from the host device 2 to the recording medium 1. As a result, the recording medium 1 is activated. When the host device 2 transmits data to the activated recording medium 1, this data is stored in the nonvolatile semiconductor memory cache 61 via a data terminal.

Assume that the transmitted data has been stored in the nonvolatile semiconductor memory cache 61 and the stored data is unrecorded in the memory area 51. In this state, assume that the recording medium 1 has been removed from the card slot, as shown in FIG. 16C. In this state, the power Vdd, Vss is not supplied to the recording medium 1, and thus, the recording medium 1 is deactivated. However, the cache memory 61 of this modified example is a nonvolatile semiconductor memory, and thus, even if the recording medium 1 is deactivated, the stored data is not lost.

When the recording medium 1 shown in FIG. 16C is inserted again into the card slot of the host device 2, as shown in FIG. 16D, the power Vdd, Vss is supplied to the recording medium 1, and then, the recording medium 1 is reactivated. Then, while an access is not provided from the host device 2 to the activated recording medium 1, the data stored in the nonvolatile semiconductor memory cache 61 and unrecorded in the memory area 51 is recorded as binary data in a binary area 55 of the memory area 51.

Further, as shown in FIG. 16E, the data recorded in the binary area 55 is copied as multi-level data to a multi-level area 57 of the memory area 51 when no access is provided from the host device 2.

As described above, in the case where the cache 61 is a nonvolatile semiconductor memory cache and the data stored in this nonvolatile semiconductor memory cache 61 is unrecorded in the memory area 51, the unrecorded data can be recorded in the binary area 55 of the memory area 51 when the nonvolatile semiconductor memory cache 61 and the memory area 51 are reconnected to the host device 2.

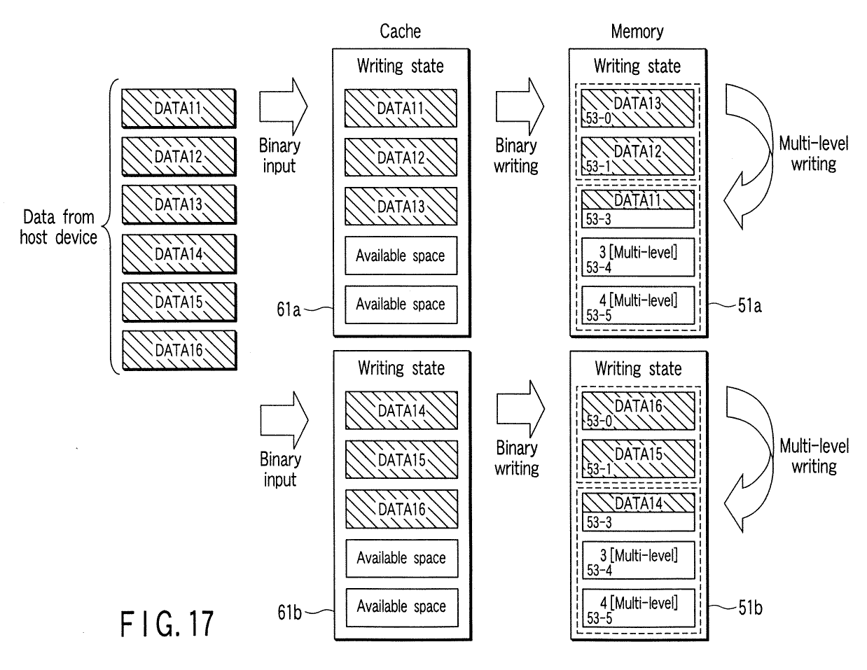

In addition, as shown in FIG. 17, the cache 61 is arranged in parallel, like caches 61a and 61b, and further, the memory area 51 is also arranged in parallel like memory areas 51a and 51b, whereby the lowering of a recording speed can be further mitigated.

While the present invention has been described in accordance with the first to fourth embodiments, the invention according to the firth to fourth embodiments can attain advantages as described below.

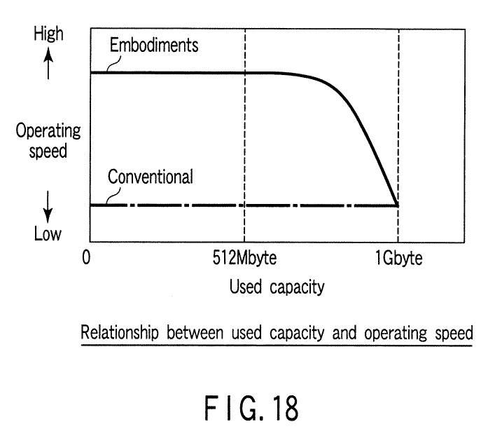

FIG. 18 is a view showing a relationship between a used capacity and an operating speed.

FIG. 18 shows a relationship between a used capacity and an operating speed of a typical multi-level non-volatile semiconductor memory (Conventional) and a relationship between a used capacity and an operating speed of a multi-level nonvolatile semiconductor memory (Embodiments) utilizing the recording system according to the embodiments described above. The recording capacity of the multi-level nonvolatile semiconductor memory (Conventional) and that of the multi-level nonvolatile semiconductor memory (Embodiments) each are 1 Gbyte.

As shown in FIG. 18, in the multi-level nonvolatile semiconductor memory (Conventional), an operating speed does not change from a time of starting use (when the used capacity is zero) to a time of ending use (when the used capacity is 1 Gbyte). In contrast, in the multi-level nonvolatile semiconductor memory (Embodiments), an operating speed at the time of starting use (when the used capacity is zero) is higher than that of the conventional memory, and the operating speed at the time of ending use is equal to that of the conventional memory.

As described above, according to the embodiments, there can be provided a data recording system of a semiconductor integrated circuit device having a nonvolatile semiconductor memory that achieves high speed data writing and data reading.

In addition, the above embodiments include the following aspects.

(1) A data recording system of a semiconductor integrated circuit device which has a memory area including a binary area and a multi-level area, and exchanges data between the memory area and a host device, the system comprising:

recording data transmitted by the host device as binary data in the binary area; and

copying the data recorded in the binary area as multi-level data to the multi-level area when no access is provided from the host device.

(2) The data recording system according to the aspect (1), wherein, after the data recorded in the binary area is copied to the multi-level area, the data recorded in the binary area is left in the binary area.

(3) The data recording system according to the aspect (2), wherein, when a data read request is made from the host device and data corresponding to the read request exists in the binary area, the data is read from the binary area.

(4) The data recording system according to the aspect (1), wherein, when no available space is left in the binary area, among the data recorded in the binary area, the data transmitted from the host device is recorded in an overwritten manner in a portion at which the data copied to the multi-level area exists.

(5) The data recording system according to the aspect (1), wherein, when no available space is left in the multi-level area, the binary area is partially changed to a multi-level area.

(6) The data recording system according to the aspect (5), wherein, among the binary area, a portion at which the data copied to the multi-level area exists is changed to the multi-level area.

(7) The data recording system according to the aspect (1), wherein a cache is further provided, the data transmitted from the host device is stored in the cache, and the data stored in the cache is recorded in the binary area of the memory area.

(8) The data recording system according to the aspect (7), wherein, in the case where the cache is a nonvolatile semiconductor memory cache and the data stored in the nonvolatile semiconductor memory cache is unrecorded in the memory area, the unrecorded data is recorded in the binary area of the memory area when the nonvolatile semiconductor memory cache and the memory area are reconnected to the host device.

(9) The data recording system according to the aspect (7) or (8), wherein the cache and the memory area are provided in plurality, respectively,

the data transmitted from the host device is divided to be stored in parallel in the plurality of caches, and

the data stored in the plurality of caches each are recorded in the binary area of each one of the plurality of memory areas.

While the present invention has been described by way of some embodiments, the present invention is not limited to each of the embodiments. When carrying out the invention, various modifications can be made without departing from the spirit of the invention.

The embodiments can be carried out solely or in proper combination.

In addition, the embodiments include inventions of various stages, and the inventions of various stages can be excerpted from proper combinations of a plurality of constituent requirements disclosed in the embodiments.

In addition, while the embodiments have been described by way of example in which the present invention has been applied to a NAND-type flash memory, the present invention can also be applied to an a flash memory other than NAND-type, such as AND- or NOR-type. Further, the present invention also encompasses a semiconductor integrated circuit device having these flash memories incorporated therein, such as a processor or a system LSI, for example.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A data recording method of a semiconductor integrated circuit device which has a memory area including a binary area and a multi-level area, and exchanges data between the memory area and a host device, the method comprising:
recording data transmitted by the host device as binary data in the binary area; and
copying the data recorded in the binary area as multi-level data to the multi-level area when no access is provided from the host device.

2. The data recording method according to claim 1, wherein, after the data recorded in the binary area is copied to the multi-level area, the data recorded in the binary area is left in the binary area.

3. The data recording method according to claim 2, wherein, when a data read request is made from the host device and data corresponding to the read request exists in the binary area, the data is read from the binary area.

4. The data recording method according to claim 1, wherein, when no available space is left in the binary area, among the data recorded in the binary area, the data transmitted from the host device is recorded in an overwritten manner in a portion at which the data copied to the multi-level area exists.

5. The data recording method according to claim 1, wherein, when no available space is left in the multi-level area, the binary area is partially changed to a multi-level area.

6. The data recording method according to claim 5, wherein, among the binary area, a portion at which the data copied to the multi-level area exists is changed to the multi-level area.

7. The data recording method according to claim 1, wherein a cache is further provided, the data transmitted from the host device is stored in the cache, and the data stored in the cache is recorded in the binary area of the memory area.

8. The data recording method according to claim 7, wherein, in the case where the cache is a nonvolatile semiconductor memory cache and the data stored in the nonvolatile semiconductor memory cache is unrecorded in the memory area, the unrecorded data is recorded in the binary area of the memory area when the nonvolatile semiconductor memory cache and the memory area are reconnected to the host device.

9. The data recording method according to claim 7, wherein the cache and the memory area are provided in plurality, respectively,
the data transmitted from the host device is divided to be stored in parallel in the plurality of caches, and
the data stored in the plurality of caches each are recorded in the binary area of each one of the plurality of memory areas.

10. The data recording method according to claim 8, wherein the nonvolatile semiconductor memory cache and the memory area are provided in plurality, respectively,
the data transmitted from the host device is divided to be stored in parallel in the plurality of nonvolatile semiconductor memory caches, and
the data stored in the plurality of nonvolatile semiconductor memory caches each are recorded in the binary area of each one of the plurality of memory areas.

11. The data recording method according to claim 1, wherein the memory area stores a binary/multi-level area management table indicating addresses of the binary area and addresses of the multi-level area.

12. The data recording method according to claim 11, wherein when data is written in the memory area, the binary area shown in the binary/multi-level area management table is accessed.

13. The data recording method according to claim 11, wherein the memory area includes a management data area, a security data area, a protect data area, and a user data area, and
the binary/multi-level area management table is stored in one of the security data area and the protect data area.

14. The data recording method according to claim 11, wherein:
another memory area different from the memory area is provided;
when a power supply is turned on, the binary/multi-level area management table is read out from the memory area and saved in said another memory area; and
when the data is written in the memory area, the binary area shown in the binary/multi-level area management table saved in said another memory area is accessed.

15. The data recording method according to claim 11, wherein:
when data is written in the memory area, a check is made to see whether the binary area shown in the binary/multi-level area management table includes a free space, and
if the free space is not available, the binary/multi-level area management table stored in the memory area is updated.

16. The data recording method according to claim 15, wherein the binary/multi-level area management table is updated by changing that part of the binary area from which data is copied to the multi-level area to the multi-level data.

17. The data recording method according to claim 16, wherein the binary area is changed in a stepwise manner.

18. The data recording method according to claim 11, wherein:
another memory area different from the memory area is provided;
when a power supply is turned on, the binary/multi-level area management table is read out from the memory area and saved in said another memory area;
when the data is written in the memory area, a check is made to see whether the binary area shown in the binary/multi-level area management table includes a free space;
if the free space is not available, the binary/multi-level area management table stored in the memory area is updated; and
the updated binary/multi-level area management table is read out from the memory area and is saved in said another memory area.

19. The data recording method according to claim 18, wherein the binary/multi-level area management table is updated by changing that part of the binary area from which data is copied to the multi-level area to the multi-level data.

20. The data recording method according to claim 19, wherein the binary area is changed in a stepwise manner.
